(19) United States
(12) Patent Application Publication
(10) Pub. No.: US 2013/0063183 A1
(43) Pub. Date: Mar. 14, 2013

(54) SIGNAL GENERATING APPARATUS AND METHOD OF GENERATING SIGNAL

(71) Applicants: Yoshinori Nakane, Fujisawa (JP); Yoshito Koyama, Kawasaki (JP); Koji Nakamuta, Yokohama (JP)

(72) Inventors: Yoshinori Nakane, Fujisawa (JP); Yoshito Koyama, Kawasaki (JP); Koji Nakamuta, Yokohama (JP)

(73) Assignee: FUJITSU LIMITED, Kawasaki-shi (JP)

(21) Appl. No.: 13/561,720

(22) Filed: Jul. 30, 2012

(30) Foreign Application Priority Data
Sep. 14, 2011 (JP) 2011-200697

(51) Int. Cl. H03B 21/00

(52) U.S. Cl. 327/107

(57) ABSTRACT

A signal generating apparatus includes: a direct digital synthesizer configured to generate an output signal of a frequency according to first control data based on a reference clock; and a controller configured to provide the direct digital synthesizer with the first control data at a timing synchronized with the reference clock, wherein the controller includes a table which stores second setting data for controlling the frequency of the output signal based on jitter information and provides the direct digital synthesizer with the second setting data in the table as the first control data at the timing.

### CROSS-REFERENCE TO RELATED APPLICATION(S)

This application is based upon and claims the benefit of priority of the prior Japanese Patent Application No. 2011-200697, filed on Sep. 14, 2011, the entire contents of which are incorporated herein by reference.

### FIELD

The embodiment discussed herein is related to a signal generating apparatus and a method of generating signal.

### BACKGROUND

In a jitter tolerance test corresponding to a load test of a receiving device, whether a target device, which receives a signal that a jitter is added to, works correctly or not is checked. Components of the added jitters may be changed so that the target device may be evaluated on what type of jitters is tolerated for the target device. The jitter tolerance test is performed using a measuring instrument for test.

Japanese Laid-open Patent Publication No. 2006-60451 discusses a related art.

### SUMMARY

According to one aspect of the embodiments, a signal generating apparatus includes: a direct digital synthesizer configured to generate an output signal of a frequency according to first control data based on a reference clock; and a controller configured to provide the direct digital synthesizer with the first control data at a timing synchronized with the reference clock, wherein the controller includes a table which stores second setting data for controlling the frequency of the output signal based on jitter information and provides the direct digital synthesizer with the second setting data in the table as the first control data at the timing.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 depicts an exemplary signal generating apparatus;

FIG. 2 depicts an exemplary relationship between frequencies and passing power;

FIG. 3 depicts an exemplary control circuit;

FIGS. 4A and 4B depict an exemplary jitter control table;

FIGS. 5A and 5B depict an exemplary jitter control table;

FIG. 6 depicts an exemplary output clock;

FIGS. 7A and 7B depict an exemplary jitter control table;

FIGS. 8A and 8B depict an exemplary jitter control table;

FIGS. 9A and 9B depict an exemplary jitter adding test; and

FIG. 10 depicts an exemplary signal generating apparatus.

### DESCRIPTION OF EMBODIMENT

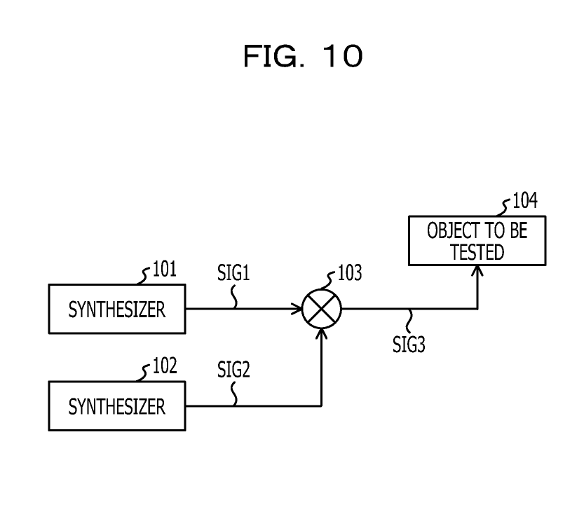

By mixing a modulating signal of around 1kHz-10MHz with a radio frequency carrier signal (main signal) by a mixer, a signal to which a jitter to be provided to a target device is added may be generated. FIG. 10 depicts an exemplary signal generating circuit. A carrier signal SIG1 generated by a first synthesizer 101 and a modulating signal SIG2 generated by a second synthesizer 102 are mixed by a mixer 103. The mixer 103 provides a device under test 104 with a modulated signal SIG3 so that a jitter tolerance test is performed.

A mixer mixes a carrier signal and a modulating signal resulting in that a signal waveform may possibly be distorted and that power for signal amplification may possibly increase. Workloads of checks and adjustments for adding a desirable quantity of jitters may possibly increase.

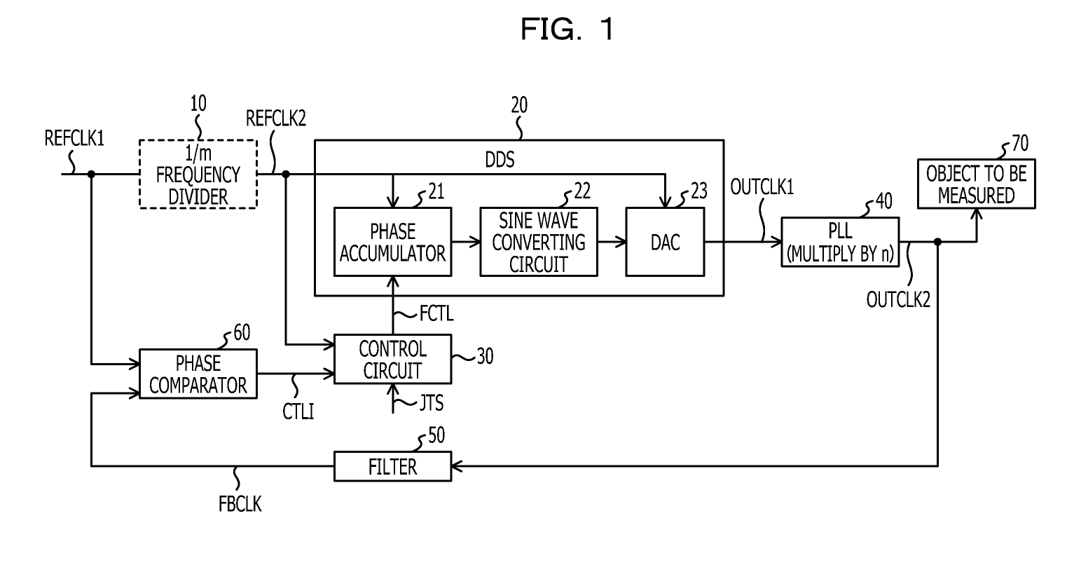

FIG. 1 depicts an exemplary signal generating apparatus. The signal generating apparatus includes a frequency divider 10, a direct digital synthesizer (DDS) 20, a control circuit 30, a phase locked loop (PLL) circuit 40, a filter 50 and a phase comparator 60. What is given a reference numeral 70 in FIG. 1 is an object to be measured (device under test) and may be, e.g., a receiving device.

The frequency divider 10 frequency-divides an input reference clock REFCLK1 so as to output a reference clock REFCLK2 of a one m-th frequency. The frequency divider 10 provides the DDS 20 and the control circuit 30 with the reference clock REFCLK2. The frequency divider 10 may be omitted and the reference clock REFCLK1 may be supplied to the DDS 20 and the control circuit 30.

The DDS 20 operates with reference to the input reference clock REFCLK2 and generates an output clock OUTCLK1 of a frequency specified by control data (tuning words) FCTL based on the frequency of the reference clock. The reference clock of the DDS 20 may be the reference clock REFCLK2. The reference clock REFCLK2 may be a multiplied or divided clock. The DDS 20 includes a phase accumulator 21, a sine wave converting circuit 22 and a digital-to-analog converting circuit (DAC) 23. The DDS 20 may include a low-pass filter which filters an output of the DAC 23, although not depicted in FIG. 1.

The phase accumulator 21 decides an increment of phase setting data in accordance with the frequency specified by the input control data FCTL and accumulates the phase setting data based on the reference clock REFCLK2. The accumulated phase setting data is provided to the sine wave converting circuit 22. The sine wave converting circuit 22 includes a lookup table related to amplitude data of a sine wave. The phase setting data provided by the phase accumulator 21 is converted into amplitude data of a corresponding sine wave by the sine wave converting circuit 22 and is provided to the DAC 23. The DAC 23 digital-to-analog converts the amplitude data of the sine wave provided by the sine wave converting circuit 22 into the output clock OUTCLK1 based on the reference clock REFCLK2 and outputs OUTCLK1.

The control circuit 30 includes a jitter control table onto which an amount of fluctuation of an output frequency is mapped for one cycle of a jitter frequency. Setting data for one cycle provided to the DDS 20 as the control data (tuning words) FCTL for generating a signal that a jitter is added to is stored in the jitter control table for a write timing. The control circuit 30 chooses a jitter control table according to a frequency and a depth (magnitude) of a jitter specified based on input jitter setting data JTS, and provides the DDS 20 with setting data filed in the chosen jitter control table as the control data FCTL. The control circuit 30 provides the DDS 20 with the control data FCTL at a timing which is synchronized with the reference clock of the DDS 20, for example, REFCLK2. For example, the setting data may be provided one by one for the timing. The control data FCTL output by the control circuit 30 is rewritten into setting data to be filed in the jitter control table at the timing which is synchronized with the reference clock of the DDS 20 by turns and provided to the DDS 20. The control circuit 30 is provided with control data CTLI from the phase comparator 60. The control circuit 30 carries out a process for correcting the control data FCTL based on the control data CTLI, and provides the DDS 20 with the corrected control data FCTL.

The PLL circuit 40 multiplies the frequency of the output clock OUTCLK1 from the DDS 20 and outputs a clock of a high n-multiplied frequency as an output clock OUTCLK2. The PLL circuit 40 provides the filter 50 and the object to be measured 70 with the output clock OUTCLK2.

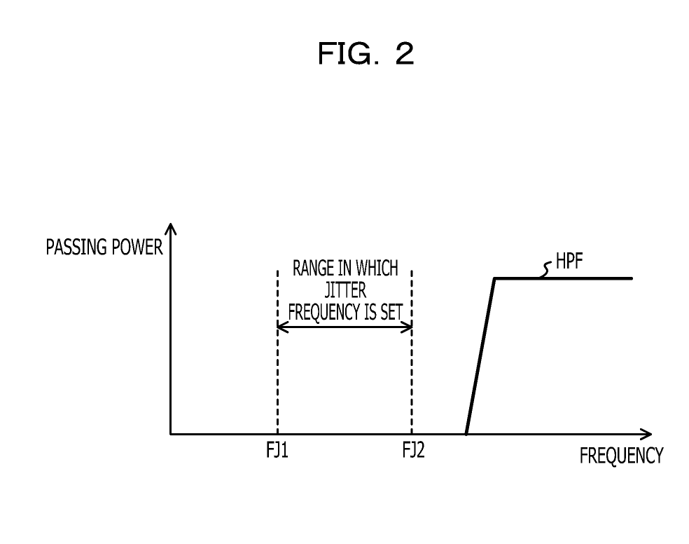

FIG. 2 depicts an exemplary relationship between frequency and passing power. The filter 50 depicted in FIG. 2 may be a high-pass filter having a frequency characteristic HPF for blocking components in a frequency range FJ1-FJ2, which is a jitter frequency setting range, and passing a component of a frequency higher than the frequency FJ2 as depicted in FIG. 2. The filter 50 may be a high-pass filter having a cut-off frequency between the frequency FJ2 and a fundamental frequency of the output clock OUTCLK2. The filter 50 removes an added jitter component from the output clock OUTCLK2 so as to output a feedback clock FBCLK.

The phase comparator 60 compares phases (frequencies) of the input reference clock REFCLK1 and the feedback clock FBCLK (jitter-removed output clock OUTCLK2) with each other, and outputs a comparison result as the control data CTLI.

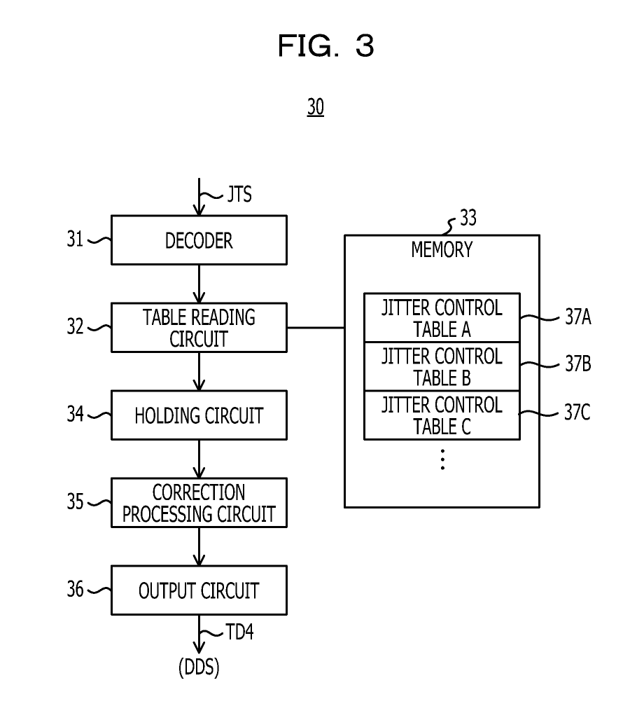

FIG. 3 depicts an exemplary control circuit. A control circuit 30 depicted in FIG. 3 may the control circuit 30 depicted in FIG. 1. The control circuit 30 includes a decoder 31, a table reading circuit 32, a memory 33, a holding circuit 34, a correction processing circuit 35 and an output circuit 36. A plurality of jitter control tables 37A, 37B, 37C and so forth which each correspond to an added jitter are filed in the memory 33.

The decoder 31 decodes the jitter setting data JTS and outputs a read address RAD for reading a jitter control table corresponding to the jitter setting data JTS from the memory 33. The table reading circuit 32 reads a jitter control table from the memory 33 based on the read address RAD provided by the decoder 31. The holding circuit 34 holds a jitter control table TD1 read by the table reading circuit 32.

The correction processing circuit 35 is provided with setting data TD2 of a jitter control table from the holding circuit 34 and the control data CTLI from the phase comparator 60 and carries out a correction process on the setting data TD2 based on the control data CTLI. The correction process may be carried out by the correction processing circuit 35 based on the control data CTLI if desired. The output circuit 36 receives setting data TD3 after the correction process and sends the setting data TD3 to the DDS 20 as setting data TD4 at the timing which is synchronized with the reference clock of the DDS 20.

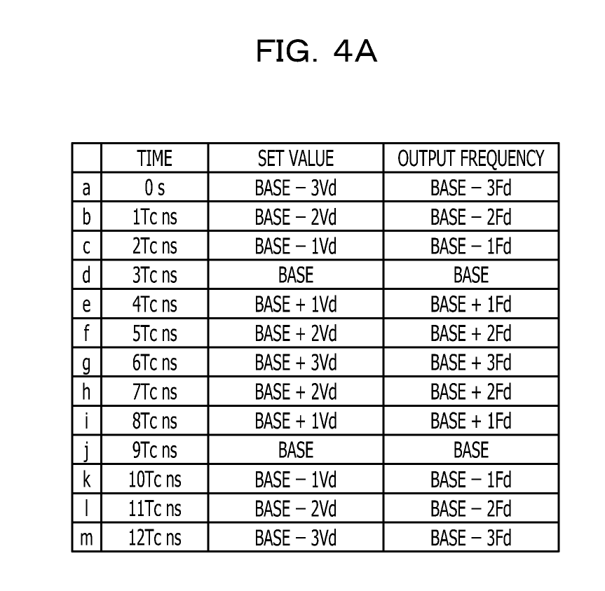

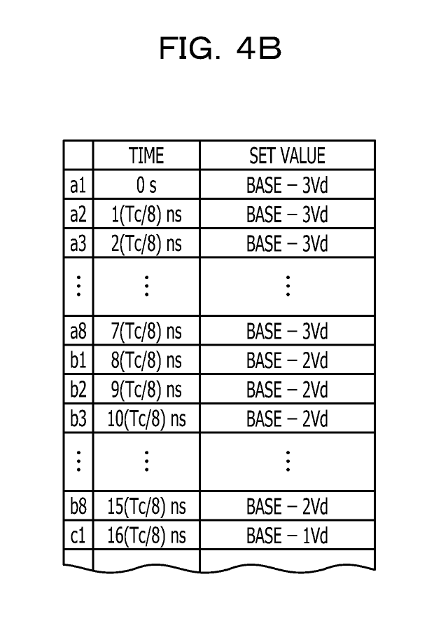

FIGS. 4A and 4B depict an exemplary jitter control table. As depicted in FIGS. 4A and 4B, e.g., a jitter of a jitter frequency (1×10⁶)/(12 Tc) [kHz] and a jitter depth (jitter magnitude) ±3 Fd may be added to a signal of a fundamental frequency BASE. The frequency change within the width of ±3 Fd with a center of the fundamental frequency BASE. The frequency of the reference clock of the DDS 20 may be (8×10³)/Tc [MHz].

The control circuit 30 provides the DDS 20 with a set value (BASE−3 Vd) corresponding to the output frequency (BASE−3 Fd) as the control data FCTL in a period of time a (0-1 Tc[ns]), e.g., as depicted in FIG. 4A, so as to generate a signal that a jitter is added to as described above. The control circuit 30 provides the DDS 20 with a set value (BASE−2 Vd) corresponding to the output frequency (BASE−2 Fd) as the control data FCTL in a period of time b (1 Tc-2 Tc[ns]). The control circuit 30 provides the DDS 20 with a set value (BASE−1 Vd) corresponding to the output frequency (BASE−1 Fd) as the control data FCTL in a period of time c (2 Tc-3 Tc[ns]). The control circuit 30 similarly changes the set value by Vd at Tc intervals, and provides the DDS 20 with the set value as the control data FCTL.

The control circuit 30 writes a set value into the DDS 20 every 8/Tc [ns]. A jitter control table depicted in FIG. 4B is set so that the set values are sent to the DDS 20 as depicted in FIG. 4A. A write operation of the set value (BASE−3 Vd) is performed eight times every 8/Tc [ns]. Then, a write operation of the set value (BASE−2 Vd) is performed eight times every 8/Tc [ns]. Then, a change operation of the set value is performed similarly every eight times.

The DDS may be used for adjusting a frequency on an oscillator for a PLL circuit. The control data (tuning words) provided to the DDS may be fixed if a signal of a single frequency is provided.

The control circuit 30 updates the control data FCTL provided to the DDS 20 at short (rapid) and regular intervals in nanoseconds or picoseconds by the use of the jitter control table. Control bits provided to the DDS 20 are changed rapidly and at regular intervals, and the frequency of the output clock OUTCLK1 periodically changes. Thus, an effect substantially same as that of frequency modulation may be obtained and a signal that a jitter is added to is generated.

As the jitter frequency or jitter depth is freely set based on the number of repetitions or a variation of the setting data filed in the jitter setting table, any jitter may be easily added. As a quantity of jitters is controlled based on the control data for the DDS 20, e.g., the setting data, an infinitesimal jitter may be added. A workload of checking and adjusting the quantity of jitters may thereby be reduced or simplified. The jitter frequency or jitter depth may be easily changed, e.g., and a test may be performed. A test may be performed based on a linear change of the quantity of added jitters. As the jitter frequency or jitter depth is changed in an instant, e.g., a tolerance to instantaneously added jitters or to abruptly changed jitters, etc., may be measured.

A variation of the output frequency for one cycle of the jitter frequency is mapped on the jitter control table, and may be repeatedly controlled. A size of a memory in which the jitter control table is to be stored may thereby be reduced, and a signal to which jitters are added is generated. As the DDS 20 generates a signal including a jitter component without using a mixer, a signal having a distortion-free waveform may be obtained and noise generation may be reduced.

In the signal generating apparatus depicted in FIG. 1, e.g., the frequencies of the jitter clocks REFCLK1, OUTCLK2 and FBCLK to which no jitters are added may be 622.08 [MHz]. The frequency of the clock REFCLK2 to which no jitters are added may be 311.04 [MHz]. The frequency of the clock OUTCLK to which no jitters are added may be 19.44 [MHz]. The reference clock of the DDS 20 may have a frequency substantially same as that of the clock REFCLK2, e.g., 311.04 [MHz].

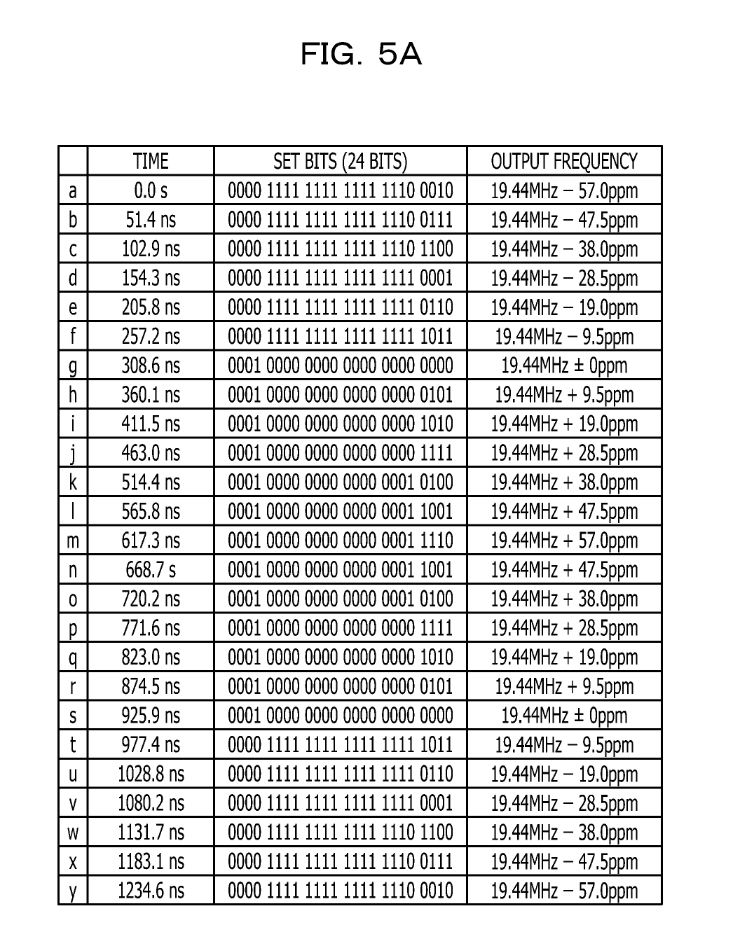

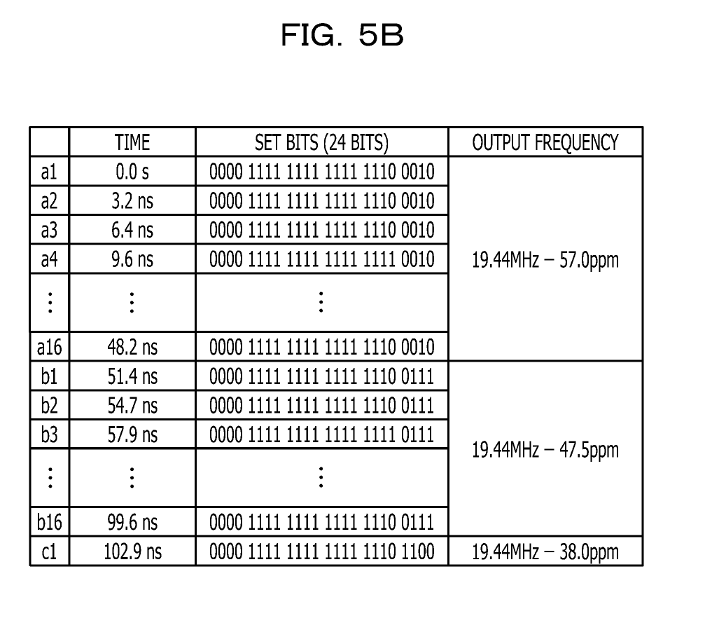

FIGS. 5A and 5B depict an exemplary jitter control table. The DDS 20 may output a signal formed by adding a jitter having a jitter frequency 810 [kHz] and a jitter depth ±57.0 [ppm] to a signal of a fundamental frequency 19.44 [MHz]. The control data of the DDS 20 may have, e.g., 24 bits in width. A frequency deviation may be controlled in units of 1/(2²⁴), i.e., 0.06 [ppm]. For example, if a deviation in one control is 9.5 [ppm], the control may be repeated 24 times in units of 9.5/0.06, i.e., 160 (32×5) steps as depicted in FIG. 5A.

The frequency of the output clock OUTCLK1 provided by the DDS 20 depicted in FIG. 5A may be controlled on based on the jitter control table depicted in FIG. 5B. The control data may be written into the DDS 20, e.g., at 3.2 [ns] (=1/311.04 MHz) intervals. Thus, setting data “0000 1111 1111 1111 1110 0010” may be written from 0 [ns] to 48.2 [ns] corresponding to the period of time a, e.g., a1 through a16. Setting data “0000 1111 1111 1111 1110 0111” is written from 51.4 [ns] to 99.6 [ns] corresponding to the period of time b, e.g., b1 through b16. Setting data according to the output frequency is similarly written into the DDS 20 for periods of time c through x.

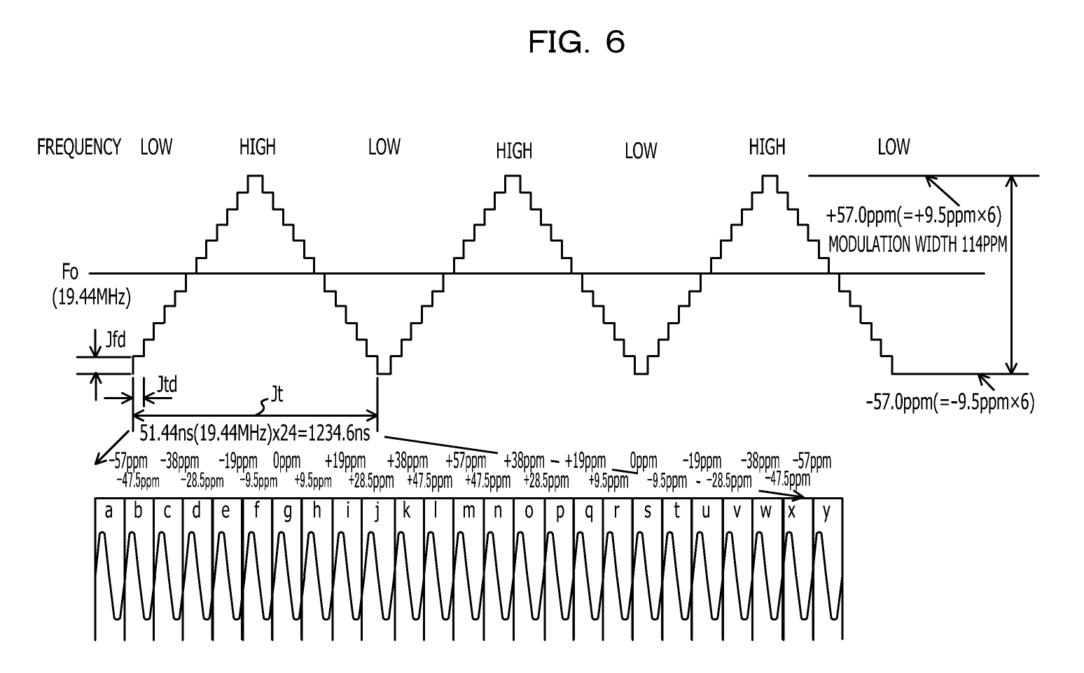

FIG. 6 depicts an exemplary output clock. FIG. 6 depicts a frequency change of the output clock OUTCLK1 provided by the DDS 20 based on the jitter control table depicted in FIG. 5B. The frequency modulation is changed over at Jtd, e.g., 51.44 [ns] intervals as depicted in FIG. 6. The jitter is controlled by a unit variation Jfd, e.g., 9.5 [ppm]. The frequency of the output clock OUTCLK1 changes within the width of ±57.0 [ppm] at the center of the fundamental frequency F0, i.e., 19.44 [MHz] in a period of time it based on the jitter control table depicted in FIG. 5B.

The frequency of the output clock OUTCLK1 provided by the DDS 20 may be out of phase while being controlled based on the setting data filed in the jitter control table. The phase comparator 60 compares the phase (frequency) of the reference clock REFCLK1 with that of the feedback clock FBCLK, and the control circuit 30 controls the control data provided to the DDS 20 based on a result of the comparison and adjusts the phase (frequency) so that the both clocks are in phase with each other.

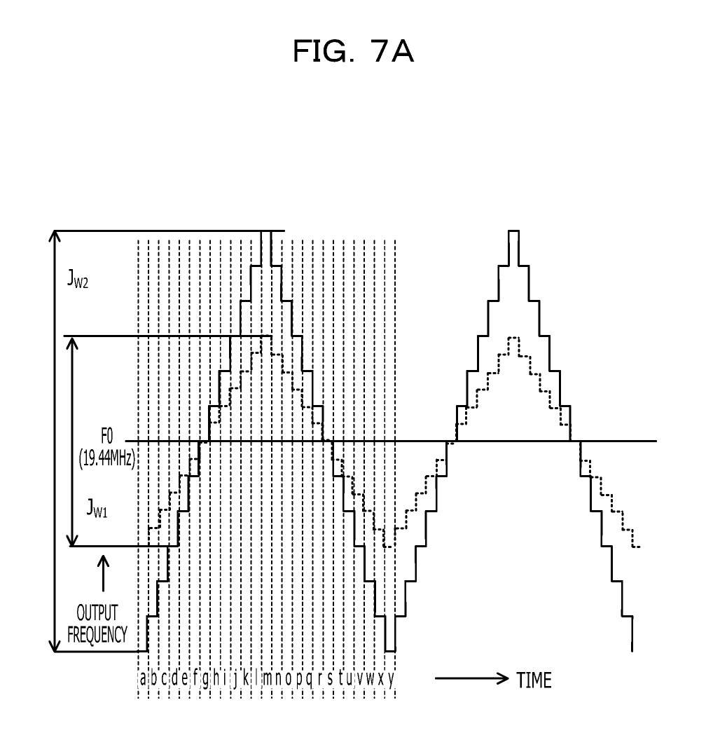

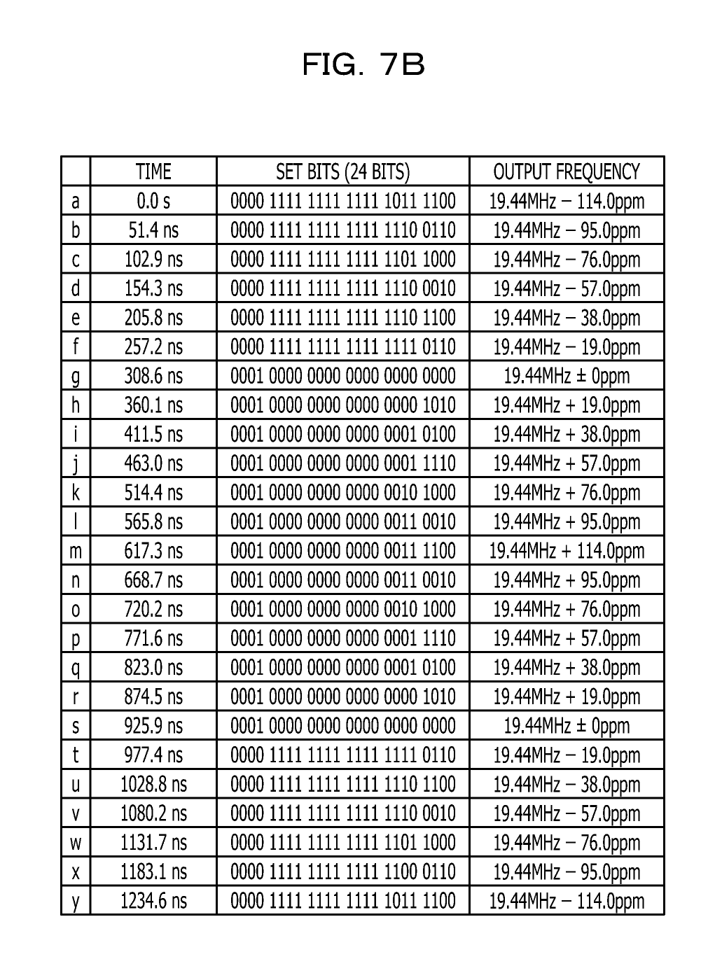

FIGS. 7A and 7B depict an exemplary jitter control table. The DDS 20 may output a signal generated by adding a jitter having a jitter frequency 810 [kHz] and a jitter depth ±114.0 [ppm] to a signal of a fundamental frequency 19.44 [MHz]. A jitter may be added to a jitter depth Jw1 (±57.0 [ppm]) with frequency changes indicated by dashed lines in FIG. 7A so that a jitter of a doubled jitter depth Jw2 indicated by solid lines may be generated.

The variation of the setting data is doubled as depicted in FIG. 7B so that the jitter depth (jitter magnitude) is doubled. The variation of the setting data is tripled so that the jitter depth (jitter magnitude) is tripled. The variation of the setting data is made N-times (N is any value) as large so that the jitter depth (jitter magnitude) is made N-times as large. A signal that a jitter made N-times as large is added to may be easily generated.

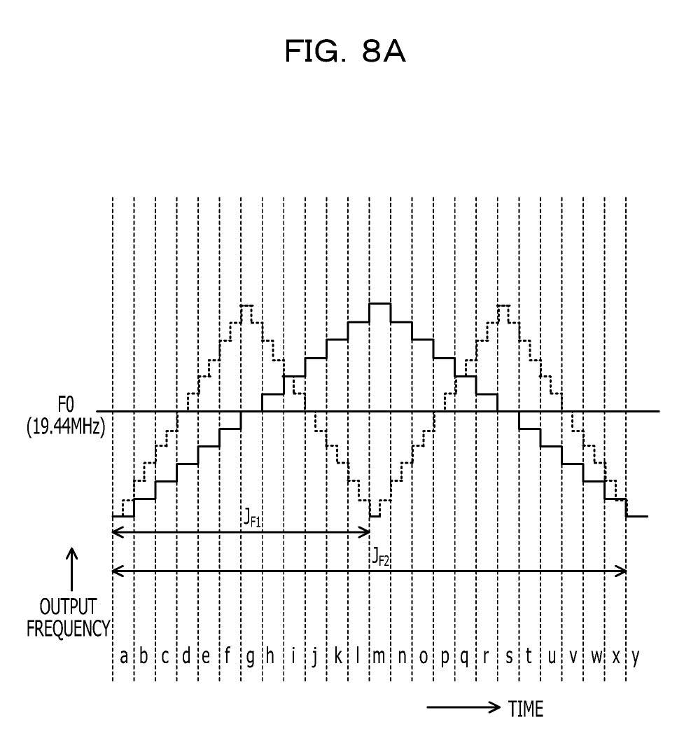

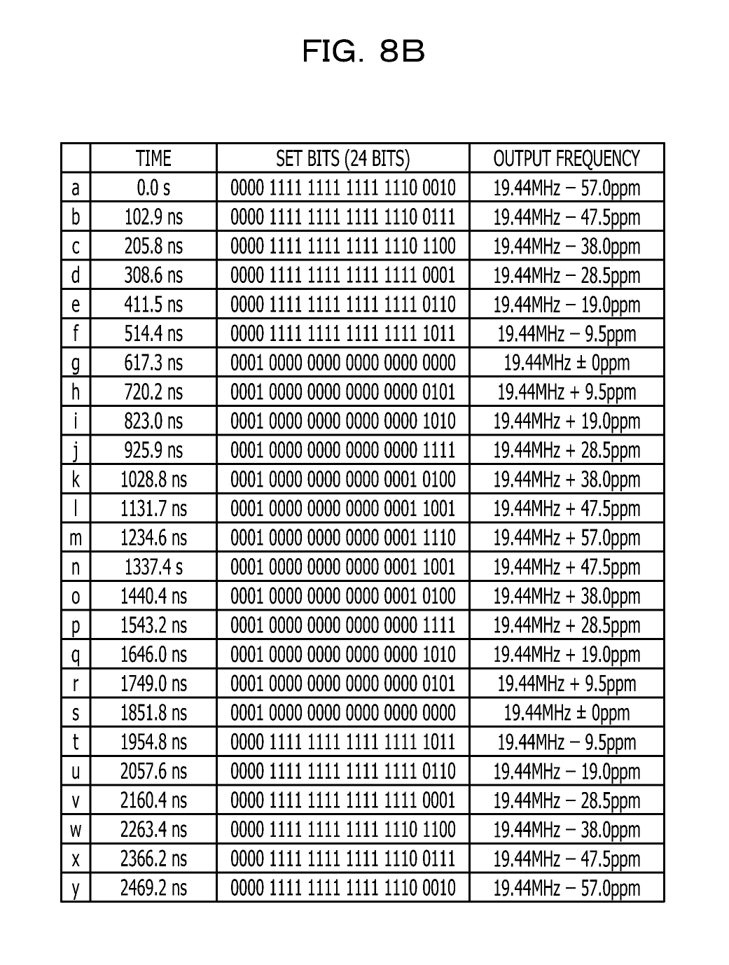

FIGS. 8A and 8B depict an exemplary jitter control table. The DDS 20 may output a signal generated by adding a jitter having a jitter frequency 405 [kHz] and a jitter depth ±57.0 [ppm] to a signal of a fundamental frequency 19.44 [MHz]. A jitter may be added to a jitter frequency JF1 (810 [kHz]) indicated by dashed lines as depicted in FIG. 8A, e.g., so that a jitter of a jitter frequency JF2 reduced by half indicated by solid lines may be generated.

A control speed of the setting data is set twice as slow as depicted in FIG. 8B so that the jitter frequency is set by half. For example, the setting data may be written twice as frequently without a change of the frequency of the reference clock of the DDS 20. The control speed of the setting data is set one tenth as slow so that the jitter frequency is set by one tenth. The control speed of the setting data is set one M-th (M is any value) as slow so that the jitter frequency is set by one M-th. A signal that a jitter of a jitter frequency reduced by one M-th is added to may be easily generated.

The jitter control tables depicted in FIGS. 7 and 8 may be combined and used. The variation of the setting data may be set to X times as large (X may be any value) and the control speed of the setting data may be set to Y times as slow (Y may be any value) in order to set the jitter depth (jitter magnitude) X times as large and to set the jitter frequency by one Y-th. Any jitter may be added based on the variation of the setting data on the jitter control table and control of timing for changing setting bits.

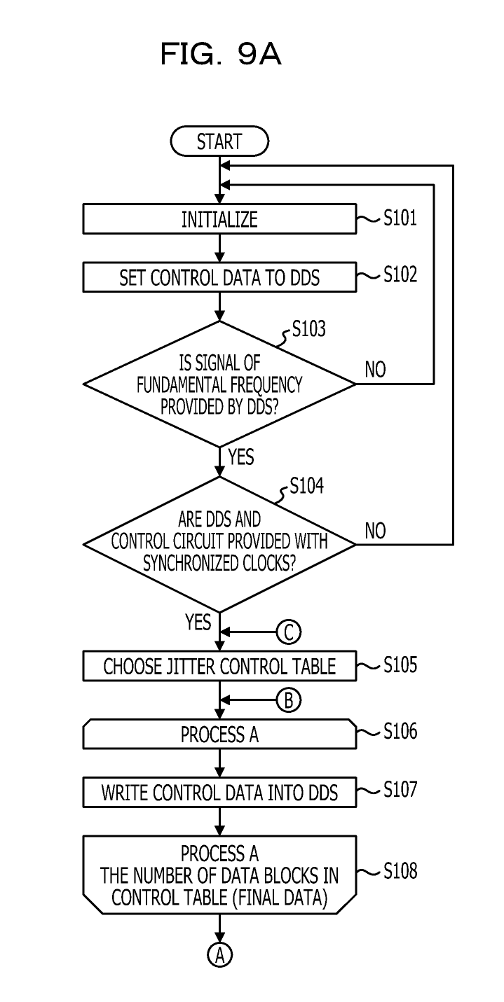

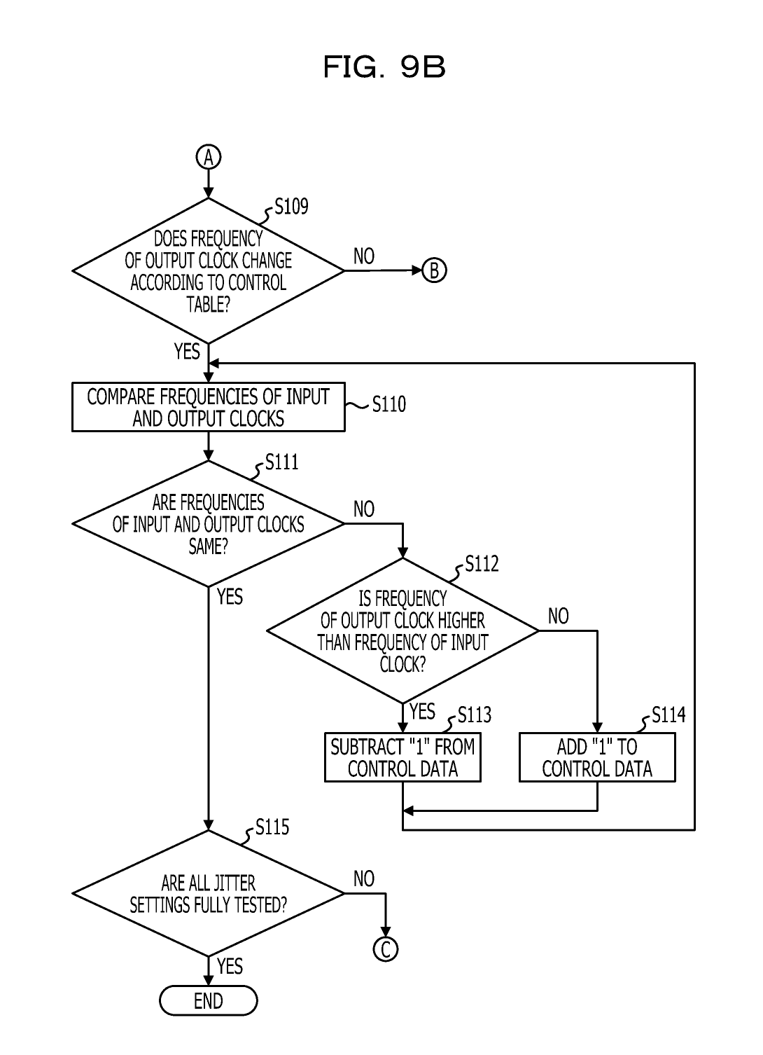

FIGS. 9A and 9B illustrate an exemplary jitter adding test. The jitter adding test depicted in FIGS. 9A and 9B may be performed by the signal generating apparatus depicted in FIG. 1.

The jitter adding test begins. The signal generating apparatus (the DDS 20 and the control circuit 30) depicted in FIG. 1, e.g., is initialized in an operation S101. After being initialized, the control circuit 30 sets the control data FCTL to the DDS 20 so as to output a signal of a fundamental frequency in an operation S102. After setting the control data FCTL as the operation S102, whether the DDS 20 outputs a signal of the fundamental frequency (S103) or not and whether the DDS 20 and the control circuit 30 are provided with synchronized clocks (S104) or not are decided. Unless the DDS 20 outputs a signal of the fundamental frequency or unless the DDS 20 and the control circuit 30 are provided with synchronized clocks, the process returns to the operation S101. If the DDS 20 outputs a signal of the fundamental frequency and the DDS 20 and the control circuit 30 are provided with synchronized clocks, the process shifts to an operation S105.

The control circuit 30 selects one of jitter control tables to set a jitter based on input jitter setting data JTS in the operation S105. For example, the control circuit 30 performs operations S106 through S108. The control circuit 30 writes setting data blocks to be filed in the selected jitter control table into the DDS 20 one by one as the control data FCTL at a timing synchronized with the reference clock of the DDS 20. The DDS 20 updates the control data at each write timing synchronized with the reference clock, and generates an output clock of a frequency according to a value of the control data. The DDS 20 generates a signal including a jitter component and outputs the signal as the output clock OUTCLK1. The output clock OUTCLK1 provided by the DDS 20 is multiplied by n by the PLL circuit 40 and is provided to the object to be measured 70.

The operations S106 through S108 may be repeated as many times as the number of the setting data blocks to be filed in the selected jitter control table. For example, if a final setting data block to be filed in the selected jitter control table is written into the DDS 20, the process shifts to an operation S109. Whether the output clock provided by the DDS 20 changes its frequency in accordance with the chosen jitter control table is decided in the operation S109. Unless the output clock changes its frequency in accordance with the selected jitter control table, the process returns to the operation S106.

If the output clock changes its frequency in accordance with the jitter control table, the process shifts to an operation S110. The phase comparator 60 compares the frequencies of the reference clock REFCLK1 corresponding to the input clock and the feedback clock FBCLK (output clock OUTCLK2 from which jitter components have been removed) in the operation S110.

If the frequencies of the input and output clocks differ from each other (NO of S111) and the frequency of the output clock is higher than the frequency of the input clock (YES of S112), the control circuit 30 subtracts “1” from the control data and the process returns to the operation 5110 (S113). If the frequencies of the input and output clocks differ from each other (NO of S111) and the frequency of the output clock is not higher than the frequency of the input clock (NO of S112), the control circuit 30 adds “1” to the control data and the process returns to the operation 5110 (S114).

The operations 5110 through S114 are repeated until the frequencies of the input and output clocks substantially equal each other. If the frequencies of the input and output clocks are substantially the same each other (YES of S111), the control circuit 30 decides whether all jitter settings have been fully tested in an operation S115. If a test which has not been tested yet, the process returns to the operation S105 and performs the operation S105 and the operations following the operation S105 with a jitter setting not having been done. If all the jitter settings are tested, the jitter adding test ends.

The DDS 20 outputs a sine wave of a frequency according to the control data FCTL. The DDS 20 may include, e.g., a lookup table related to amplitude data of a periodic signal different from a sine wave. The DDS 20 may output an output signal based on the lookup table.

When substantially the same setting data continues, that kind of the setting data is separately filed in the jitter control table. For example, a combination of the setting data and the number of consecutive setting data blocks may be filed in the jitter control table. The control circuit 30 may repeatedly output the corresponding setting data based on the filed number information.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A signal generating apparatus comprising:
a direct digital synthesizer configured to generate an output signal of a frequency according to first control data based on a reference clock; and
a controller configured to provide the direct digital synthesizer with the first control data at a timing synchronized with the reference clock,
wherein the controller includes a table which stores second setting data for controlling the frequency of the output signal based on jitter information and provides the direct digital synthesizer with the second setting data in the table as the first control data at the timing.

2. The signal generating apparatus according to claim 1, wherein the jitter information includes a frequency and a magnitude of the jitter.

3. The signal generating apparatus according to claim 1, wherein the second setting data for one cycle is stored in the control table.

4. The signal generating apparatus according to claim 1, wherein the table includes a plurality of control tables.

5. The signal generating apparatus according to claim 4 wherein the controller selects at least one of the plurality of control tables based on the jitter information.

6. The signal generating apparatus according to claim 1 further comprising, a phase comparator configured to compare the reference clock with the output signal of the direct digital synthesizer,
wherein the controller corrects the first control data based on an output of the phase comparator.

7. The signal generating apparatus according to claim 1 further comprising, a phase locked loop circuit configured to multiply the output signal of the direct digital synthesizer.

8. The signal generating apparatus according to claim 1, wherein the setting data for each of cycles of the reference clock is stored in the table.

9. A method of generating signal, comprising:
outputting an output signal having a frequency according to first control data, the output signal being generated by a direct digital synthesizer based on a reference clock; and
providing the direct digital synthesizer with second setting data stored in a table for controlling the frequency of the output signal according to jitter information at a timing synchronized with the reference clock.

10. The method according to claim 9, wherein the jitter information includes a frequency and a magnitude of the jitter.

11. The method according to claim 9, further comprising:
comparing a phase of the reference clock with a phase of the output signal of the direct digital synthesizer; and
correcting the first control data based on a comparison result.
